(19) United States
(12) Patent Application Publication
(10) Pub. No.: US 2003/0044534 A1
(43) Pub. Date: Mar. 6, 2003

(54) Multi-pin epoxy writing apparatus

(76) Inventors: Siu Wing Lau, Kowloon (HK); Yuk Cheung Au, Kowloon (HK)

Correspondence Address: James A. LaBarre, BURNS, DOANE, SWECKER & MATHIS, L.L.P., P.O. Box 1404, Alexandria, VA, 22313-1404, US

(21) Appl. No.: 09/946,588

(22) Filed: Sep. 6, 2001

(51) Int. Cl. H01L 21/302

(52) U.S. Cl. 427/256; 438/712; 118/300

(57) ABSTRACT

A writing head for an epoxy writing apparatus is formed with two outlet pins to enable two locations to be provided with liquid epoxy at the same time, thus doubling the operational speed of the writing apparatus. The writing head may be provided with a removable and replaceable discharge member so that different outlet pin spacings can be provided.

### FIELD OF THE INVENTION

This invention relates to an apparatus for writing an epoxy pattern onto a substrate in a process such as die bonding. In particular the invention relates to such an apparatus that is capable of increasing the speed of epoxy writing.

### BACKGROUND OF THE INVENTION

In a number of semiconductor manufacturing processes, such as die bonding, it is necessary to apply a pattern of liquid silver epoxy to a substrate such as a ball grid array substrate or a lead frame to which a semiconductor component is to be attached. Conventionally the liquid epoxy is applied by means of what is known as an epoxy writing head. The epoxy writing head may include a reservoir for holding a supply of epoxy, a metering valve for delivering precise metered amounts of epoxy, and a nozzle outlet through which the metered epoxy is applied to the substrate. In use the nozzle is moved in the X and Y directions in a controlled pattern over the substrate so as to deposit epoxy where required.

A disadvantage of conventional epoxy writing apparatus, however, is the time taken to deposit epoxy over the substrate as the writing head has to move in a desired pattern. Even if the speed of movement of the writing head is increased, the overall speed of the writing operation is limited by the rate of flow of the liquid epoxy out of the outlet nozzle. As a consequence of the difficulty of providing high-speed epoxy writing, the epoxy writing step often becomes a bottle neck in the semiconductor manufacturing processes, as increasingly pick and place apparatus are able to place semiconductor dies on a substrate faster than the epoxy writing head can place the liquid epoxy.

One known method for increasing the speed with which the epoxy can be applied to the substrate is to use a so-called “shower head”. In such a system an epoxy delivery head is provided with a plurality of outlets arranged in a pattern corresponding to the desired epoxy pattern to be deposited on the substrate. Epoxy is supplied to all the outlets substantially simultaneously and the epoxy is thus deposited in the desired pattern on the substrate. While this method is faster than epoxy writing when actually depositing epoxy, unfortunately that benefit is lost when it is appreciated that for each different pattern a different “shower head” must be provided and time is taken in changing the shower heads. Furthermore it is generally inconvenient to have to retain a large number of different shower heads, whereas an epoxy writing head can easily be reprogrammed to move in a different pattern and an epoxy writing apparatus may store in a memory a large number of different preprogrammed patterns that can be recalled when needed.

### SUMMARY OF THE INVENTION

According to the present invention there is provided epoxy writing apparatus comprising a writing head and means for moving the head in a plane parallel to a surface to which epoxy is to be applied, wherein the writing head comprises two outlets for the epoxy.

Preferably the writing head comprises an epoxy discharge member comprising first and second parts, the second part including the epoxy outlets and being removably attached to the first part.

In a preferred embodiment flow directing means are provided within the discharge member for evenly dividing the flow of epoxy between the epoxy outlets.

Viewed from another aspect the present invention provides a writing head for an epoxy writing apparatus comprising an epoxy discharge member formed with at least two outlets for the discharge of epoxy to a surface during an epoxy writing operation.

Viewed from yet another aspect the present invention provides a method of depositing epoxy on a surface comprising the steps of: providing a writing head with a supply of epoxy, and moving said writing head over said surface and depositing epoxy at predefined locations, wherein said writing head deposits epoxy at two said locations simultaneously.

### BRIEF DESCRIPTION OF THE DRAWINGS

An embodiment of the invention will now be described by way of example and with reference to the accompanying drawings, in which:

FIG. 1 is a perspective view of an embodiment of the present invention in use,

FIG. 2 is a detail of FIG. 1 showing the application of epoxy to a substrate, and

FIG. 3 is a cross-section through an epoxy outlet of the embodiment of FIGS. 1 and 2.

### DETAILED DESCRIPTION OF PREFERRED EMBODIMENT

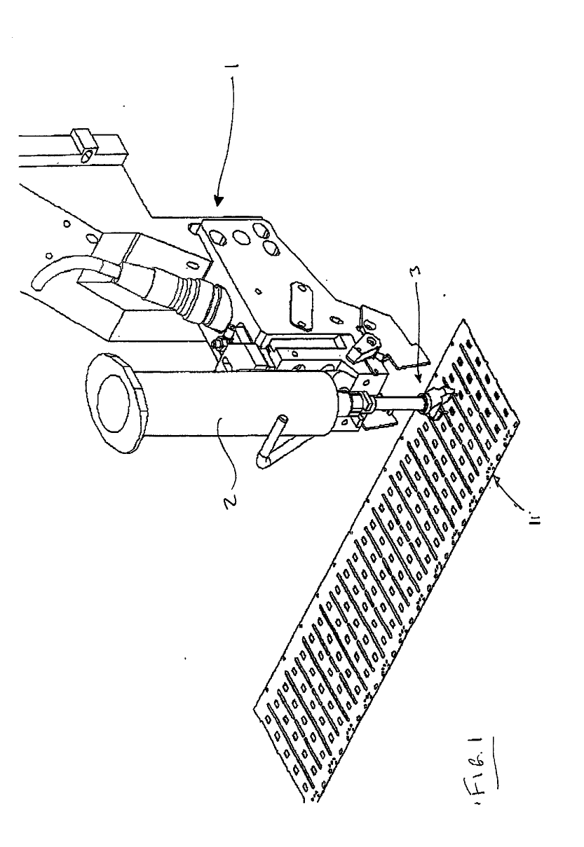

Referring firstly to FIG. 1 there is shown an epoxy writing apparatus according to an embodiment of the present invention. The apparatus comprises an epoxy writing head 1 that includes a reservoir 2 for receiving a supply of liquid epoxy. As will be understood the writing head also includes a metering valve for supplying accurate doses of epoxy to an outlet member 3. The metering valve will not be described in detail as it may take any conventional form. It will also be understood that the epoxy writing head is mounted for movement in the X and Y directions parallel to a substrate on which epoxy is to be deposited, and also in the Z direction perpendicular to the substrate. As such, the epoxy writing head described above is conventional and does not need further explanation.

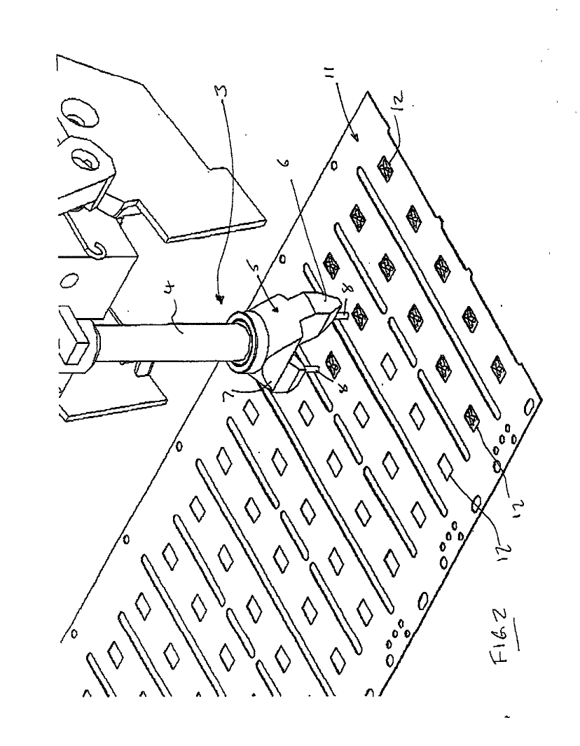

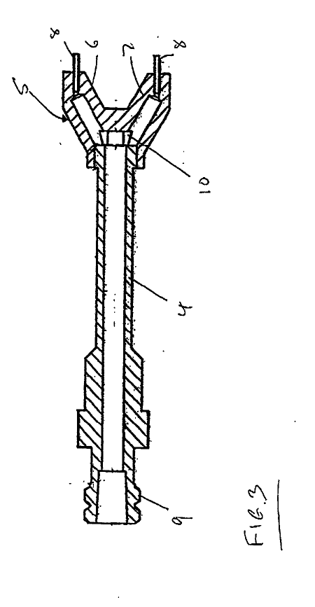

The outlet member 3 is shown more clearly in the expanded view of FIG. 2 and is shown in detail in section in FIG. 3. The outlet member 3 comprises a first cylindrical portion 4 and a second outlet pin portion 5. The outlet pin portion 5 is bifurcated into two limbs 6,7 each being formed with a respective outlet pin 8 through which epoxy may be discharged, and the outlet pin portion 5 is so sized that it may be push fit over one end of the cylindrical portion 4. The other end of the cylindrical portion 4 is provided with a screw thread 9 for attachment to the writing head, such that the outlet pin portion 5 may be removed and replaced by another outlet pin portion without having to remove cylindrical portion 4 from the writing head. Located between the end of the cylindrical portion 4 and the outlet pin portion 5 is a flow dividing member 10 that serves to ensure that epoxy flows equally into both limbs 6,7 of the bifurcated outlet pin member.

FIGS. 1 and 2 both show the epoxy writing head of this preferred embodiment of the invention in use applying epoxy to a substrate 11. The substrate 11 may be a ball grid array substrate or a lead frame, or indeed any other substrate to which epoxy must be applied before the attachment of a semiconductor element such as a die in a die bonding process. In the example of FIGS. 1 and 2 epoxy must be applied to a rectangular array of bonding locations 12 on the substrate 11. In the example shown, the substrate is a relatively elongate strip formed with a succession of transverse rows of five die locations 12 to which epoxy must be added. A conventional epoxy writing head formed with only a single pin for discharging epoxy would move transversely across the strip applying epoxy to each of the five locations in a transverse row in turn. When that row had been completed, the writing head would move to the next adjacent row and continue.

In the embodiment of the present invention, however, epoxy can be applied to two locations 12 in adjacent rows simultaneously as can be seen in FIGS. 1 and 2 in which the locations to which epoxy has already been applied are shown as two rows, and the first two locations of the next two rows. It will be understood that by providing two outlet pins 8 enabling two locations to be provided with epoxy at the same time, the speed of the epoxy writing head may be doubled.

The spacing of the two outlet pins 8 must of course be equal to the separation or pitch of the rows on the substrate. If the epoxy writing head is required to apply epoxy to a substrate with rows of a different spacing, then the bifurcated portion 5 may be removed and replaced by a different portion with the appropriate pin spacing.

It will be understood that the above embodiment is by way of example only, and there are a number of other ways that the present invention could be implemented. For example, while in the embodiment shown the epoxy writing head is formed with two outlet pins, it would be understood that three or more outlet pins could also be provided.

1. Epoxy writing apparatus comprising a writing head and means for moving said head in a plane parallel to a surface to which epoxy is to be applied, wherein said writing head comprises two outlets for the epoxy.

2. Apparatus as claimed in claim 1 wherein said writing head comprises an epoxy discharge member comprising first and second parts, wherein said second part includes said epoxy outlets and wherein said second part is removably attached to said first part.

3. Apparatus as claimed in claim 2 wherein means are provided within said discharge member for evenly dividing the flow of epoxy between said epoxy outlets.

4. Apparatus as claimed in claim 2 wherein said second part comprises two limbs each being formed at an end thereof with a respective outlet pin.

5. Apparatus as claimed in claim 4 wherein said outlet pins are parallel to each other.

6. Apparatus as claimed in claim 2 wherein said second part is push fit onto an end of said first part.

7. A writing head for an epoxy writing apparatus comprising an epoxy discharge member formed with at least two outlets for the discharge of epoxy to a surface during an epoxy writing operation.

8. A writing head as claimed in claim 7 wherein said discharge member comprises first and second parts, said first part being mountable on said writing head, and said second part being removably fixed to said first part and being formed with said at least two outlet pins for the discharge of epoxy to a surface.

9. A method of depositing epoxy on a surface comprising the steps of: providing a writing head with a supply of epoxy, and moving said writing head over said surface and depositing epoxy at predefined locations, wherein said writing head deposits epoxy at two said locations simultaneously.
